(19) United States
(12) Patent Application Publication
(10) Pub. No.: US 2013/0019802 A1
(43) Pub. Date: Jan. 24, 2013

(54) NOZZLE ARRANGEMENT AND CVD-REACTOR

(71) Applicant: Michael Leck, Esslingen (DE)

(72) Inventor: Michael Leck, Esslingen (DE)

(73) Assignee: centrotherm Sitec GmbH

(21) Appl. No.: 13/334,160

(22) Filed: Dec. 22, 2011

Related U.S. Application Data
(60) Provisional application No. 61/440,416, filed on Feb. 8, 2011.

(30) Foreign Application Priority Data
Dec. 23, 2010 (DE) 10 2010 056 021.9

(51) Int. Cl. B05B 1/34; C23C 16/455

(52) U.S. Cl. 118/724; 239/533.1; 118/715

(57) ABSTRACT

A nozzle arrangement has a nozzle body having an inlet, an outlet and a flow space arranged therebetween, and at least one control unit. The control unit has a control part and a setting part. The control part is movable within the flow space and defines a flow cross section within the flow space, which is sufficiently small to cause a loss of pressure at the control part upon a flow of gas through the nozzle body, the loss of pressure biasing the control part towards the outlet. The setting part is movable with the control part and has at least one section, which upon movement thereof varies the flow cross section of the outlet. At least one biasing element is provided, which biases the control part in a direction away from the outlet. Furthermore, a CVD-reactor incorporating such a nozzle arrangement in a bottom wall thereof is described.

### RELATED APPLICATIONS

This application claims the benefit of U.S. Provisional Application Ser. No. 61/440,416, filed Feb. 8, 2011, which claims the benefit of German Application No. 10 2010 056 021.9, filed Dec. 23, 2010, the subject matter, of which we incorporated herein by reference in their entirety.

### BACKGROUND OF THE INVENTION

The present invention relates to a nozzle arrangement for use in a CVD-reactor, in particular a silicon deposition reactor.

in the semiconductor technology and the photovoltaic industry it is known to produce silicon rods having high purity for example in accordance with the Siemens-method in deposition reactors, which are also called chemical vapor deposition reactors or short CVD-reactors. Initially, thin silicon rods are received in the reactors, and during a deposition process silicon is deposited thereon. The thin silicon rods are received in clamping and contacting devices, which on one hand hold the thin silicon rods in a predetermined orientation and on the other hand provide electrical contacting thereof. At their respective free ends, usually two of the thin silicon rods are electrically connected via an electrical conducting bridge, so as to form a current path. The thin silicon rods are heated by a current flow at a predetermined voltage via resistance heating to a predetermined temperature during the deposition process, in which the deposition of silicon occurs from a vapor or gas phase onto the thin silicon rods. The deposition temperature lies between 900-1350° C. and is typically between 1100 and 1200° C.

The process gas is provided in the required amount via a plurality of nozzle arrangements having a fixed flow diameter, which nozzle arrangements are typically provided at the bottom of the deposition reactor. During the deposition process in the reactor, the diameters of the silicon rods continuously increase, such that the surface area of the silicon rods increase. For a homogenous growth of the silicon rod it is therefore necessary to provide more process gas with increasing diameters of the silicon rods, i.e. a larger mass flow of the process gas has to be provided. In a nozzle arrangement having a static nozzle outlet with a fixed flow diameter, the velocity of the process gas exiting the nozzle strongly varies, which leads to a substantial change of the flow pattern within the reactor. This may cause the flow to stall or fail, thus not reaching the full heights of the process chamber and of the silicon rods. If a small diameter of the nozzle is chosen, even at the beginning, the required flow velocity for reaching the entire heights of the reactor is available This, however, leads to a substantially higher loss of pressure as the process progresses due to a higher mass flow, and is thus not economically viable. Furthermore, vibrations of the silicon rods may be caused, which in the worst case may lead to the silicon rods falling over. Furthermore, the flow of the process gas may lead to a cooling of the rods, which may lower the deposition rate overall and in particular locally at a lower end of the silicon rods. This may lead to the rods becoming unstable and to the rods potentially falling over or breaking. As may be understood from the above, the nozzle arrangement typically used, i.e. having a static nozzle outlet, may provide an approximately ideal flow velocity only for part of the process.

A controller, which controls the flow diameter of the nozzle arrangement within the process space was considered, but was found to be difficult to realize in practice due to the specific construction of the bottom plate of the deposition reactor and the aggressive environment.

Starting from the previously described prior art, it is an object of the present invention to provide an alternative nozzle design, which will be called a nozzle arrangement in the following and to provide an alternative CVD-reactor, which overcome at least one of the above problems.

### SUMMARY OF THE INVENTION

In accordance with the invention, a nozzle arrangement according to claim 1 and a CVD-reactor in accordance with claim 9 is provided. Further embodiments of the invention are claimed in the dependent claims.

In particular, a nozzle arrangement for use in a CVD reactor is provided, the nozzle arrangement comprising a nozzle body having an inlet, an outlet and a flow space therebetween, and at least one control unit having a control part and a setting part. The control part is movably arranged in the flow space and defines a flow diameter, which is smaller than the flow diameter of the inlet, within the flow space, such that when a gas flows to the nozzle body, a loss of pressure occurs at the control part. The loss of pressure biases the control part within the flow space towards the outlet. The setting part is movable with the control part and has at least one area, which upon movement thereof changes the flow diameter of the outlet. Furthermore, at least one biasing element is provided, which biases the control part within the flow space away from the outlet.

The problems discussed above may be counteracted by such a dynamic nozzle design or nozzle arrangement. The nozzle arrangement provides a design, which automatically positions the setting part for changing the flow diameter of the outlet via a loss of pressure between the inlet and the outlet. By setting the flow cross section of the control part within the flow space and by setting the biasing element, the design may achieve that the flow velocity of the gas exiting the nozzle arrangement may be kept approximately at the same level, considering the expected mass flows of process gas over a process.

Preferably, the control part is formed of a perforated plate, i.e. a plate having a plurality of holes, or at least has a portion formed as a perforated plate, in order to provide a defined flow diameter. Alternatively, also any other constriction to the flow at the control part, such as for example a gap between the outer circumference of the control part and the inner circumference of the flow space, may provide a defined flow diameter. In a preferred embodiment of the invention, the setting part is formed such that it enlarges the flow cross section of the outlet upon a movement of the control part towards the outlet and reduces the flow cross section during an opposite movement. The setting part may be formed such that it additionally changes the flow angle of the outlet upon its movement. In so doing, different outlet flow angles may be set during the process. For example, at the beginning of the process, when the rods in the process space are thin, the outlet angle may be larger, in order to better distribute the gas within the reaction space. Therefore, the setting portion may preferably be formed such that it reduces the outlet flow angle upon a movement of the control part toward the outlet and enlarges the outlet angle upon a movement in the opposite direction.

In order to achieve a good movement of the control part and/or the setting part, the one and/or the other part may be guided in a gliding manner by the nozzle body. In the area of the guide, at least one of the elements may have a surface made of PTFE.

In one embodiment, the nozzle body comprises an outlet opening section and at least one stationary flow guide element, which is at least partially arranged within the outlet opening section, wherein the setting part comprises a tube section which is at least partially arranged within the opening section, which tube section surrounds the at least one flow guide element.

The CVD-reactor comprises a process chamber defining a process space, which has at least one through opening in a bottom wall thereof, in which a nozzle arrangement of the above type is at least partially received. Such a CVD-reactor allows the advantages already discussed above. For a good flow of process gas throughout the process chamber, the nozzle arrangement is preferably arranged in substance completely within the through opening. In so doing, the gas inlet, i.e. the outlet of the nozzle arrangement may be substantially at the same level with the floor of the process chamber, which facilitates a homogeneous distribution of the process gas within the process space. The term “substantially” should include that at most 20%, preferably less than 10% of the heights of the nozzle arrangement extend into the process space.

In one embodiment of the invention the through opening is stepped, such that it defines a first section directly adjacent to the process space, which has a larger diameter than a directly adjacent second section thereof. A main part of the nozzle arrangement, i.e. more than 50% along its heights, is received in the first section of the through opening. Again, only a small portion of the heights of the nozzle arrangement should extend into the process space. Preferably, an axially facing shoulder is formed between the first and second sections of the through opening, against which the nozzle arrangement abuts in a sealing manner. In so doing, a simple and secure seal between the through opening and the nozzle body may be achieved.

In order to avoid high temperatures within the nozzle arrangement, the process chamber may have a cooling arrangement for cooling the bottom wall thereof and the nozzle arrangement may be mounted in a thermally conducting relationship to the bottom wall. This may be facilitated by a contacting foil having a high thermal conductivity.

### BRIEF DESCRIPTION OF THE DRAWINGS

The present invention will be described in more detail herein below with reference to the drawings; in the drawings:

FIG. 1 shows a schematic side view of a partial section of a CVD-reactor/gas converter;

FIG. 2 shows an enlarged sectional view of a nozzle arrangement of FIG. 1;

FIG. 3 shows a sectional view similar to FIG. 2, wherein the nozzle arrangement is in a different operational position;

FIG. 4 shows a sectional view along line IV-IV in FIG. 2;

FIG. 5 shows a sectional view along line V-V in FIG. 2;

FIG. 6 shows an enlarged sectional view of a nozzle arrangement in accordance with the second embodiment of the invention;

FIG. 7 shows an enlarged sectional view of a nozzle arrangement in accordance with a third embodiment of the invention;

FIG. 8 shows an enlarged sectional view of a nozzle arrangement in accordance with a fourth embodiment of the invention; and

FIG. 9 shows an enlarged sectional view of a nozzle arrangement in accordance with a fifth embodiment of the invention.

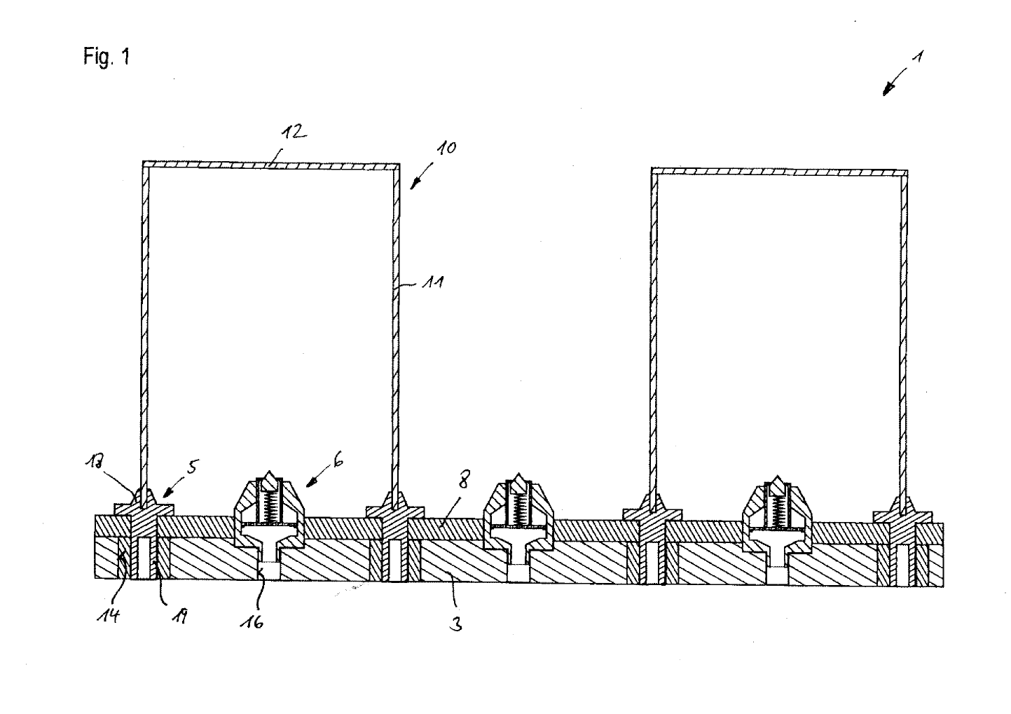

In the following description, terms such as at the top or above, at the bottom or below, right and left relate to the representation in the drawings and are not to be taken in a limiting sense, even though they may refer to a preferred orientation. Furthermore, it should be noted that the drawings are only schematic and that, in particular, the sizes in FIG. 1 are not to scale.

### DESCRIPTION OF EXEMPLARY EMBODIMENTS

FIG. 1 shows a schematic partial sectional view of a CVD-reactor, which is shown as a silicon deposition reactor. In FIG. 1 only a bottom wall 3 of a housing of the CVD-reactor 1 is shown, while the rest of the housing is not shown. Above the bottom wall 3, a process chamber of the CVD-reactor is thus formed, which is closed to the environment in an appropriate manner by housing walls, which are not shown.

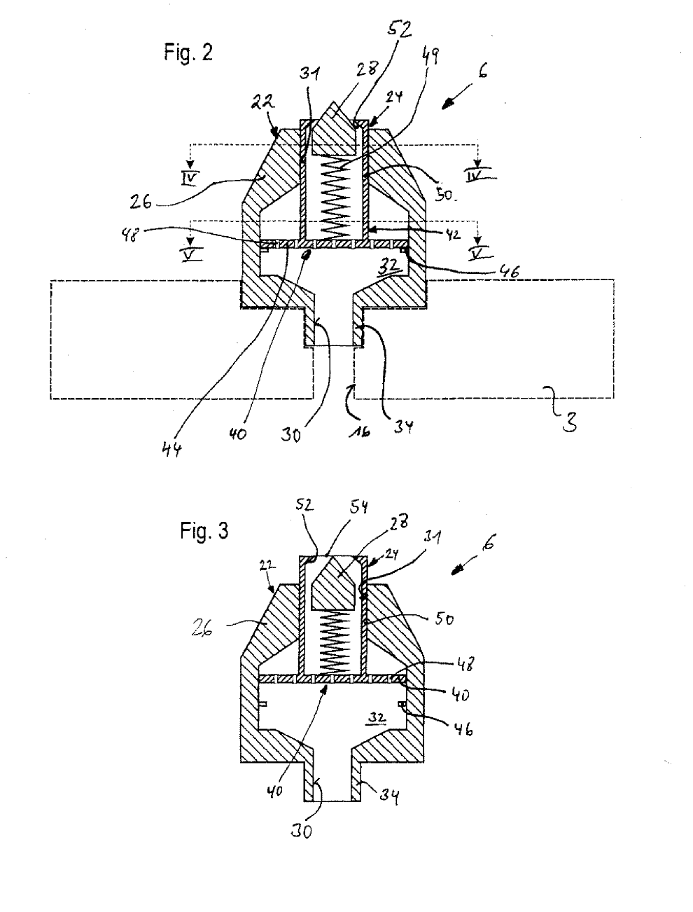

Furthermore, FIG. 1 shows electrode units 5 and nozzle arrangements 6. The nozzle arrangements 6 which form the main feature of the present invention are shown in more detail in FIGS. 2-9, which show different embodiments thereof. Adjacent to the bottom wall 3, an optional insulating unit 8 is shown, which electrically insulates the electrode unit 5 with the respect to the bottom wall 3. The insulating unit 8 may be provided only in the vicinity of the electrode units 5. In other areas, for example in the area of the nozzle arrangement, the electrical insulation may not be required. However, optionally a thermal insulation may be provided here. Furthermore, arrangements 10 of silicon rods are shown, which are formed by two vertically extending silicon rods 11, which are held by a respective electrode arrangement 5, and a horizontally extending silicon rod 12. The silicon rod 12 connects two of the silicon rods 11, as shown.

The bottom wall may be of a known type, having internal cooling passages for actively cooling the bottom wall. Furthermore, in the bottom wall 3 through openings 14 for guiding the electrode units 5 and through openings 16 for guiding the nozzle arrangements 6 through the bottom wall 6 are provided, as will be discussed in more detail herein-below. In the embodiment as shown, the through openings 14 are straight openings, while the through openings 16 are stepped openings. Obviously, this could be vice versa and also both through openings could be of the same type.

The electrode units 5 each comprise a contact part 18 arranged within the process chamber of the CVD-reactor and a connecting part 19.

The contact part 18 of the electrode units 5 is made of an electrically conducting material and is in an electrically conducting relationship to the connecting part 19, which is also made of an electrically conducting material. For example both the contact part 18 as well as the connecting part 19 may be made from graphite, since graphite does not affect the silicon deposition process within the process chamber or at least does not affect the process in a substantial manner. The connecting part 19 may be of another suitable material, such as for example copper, inasmuch as it is arranged outside of the process chamber. Alternatively, these parts may also be made of another suitable electrically conducting material. Graphite, however, is particularly beneficial, inasmuch as it may withstand the temperatures typically occurring within the process chamber.

The contact part 18 may be held in a releasable manner on the connecting part 19 and it forms a receptacle for a respective silicon rod 11 of the silicon rod arrangement 10. The receptacle is of any appropriate type, which provides for electrical contacting of the silicon rod 11 and furthermore provides a sufficient form fit, in order to hold the silicon rod 11 during the silicon deposition process in the position shown in FIG. 1.

The nozzle arrangements 6 are each of a dynamic type, which provides different cross sections of an outlet flow opening, depending on the mass flow of a process gas, as will be explained in more detail hereinbelow.

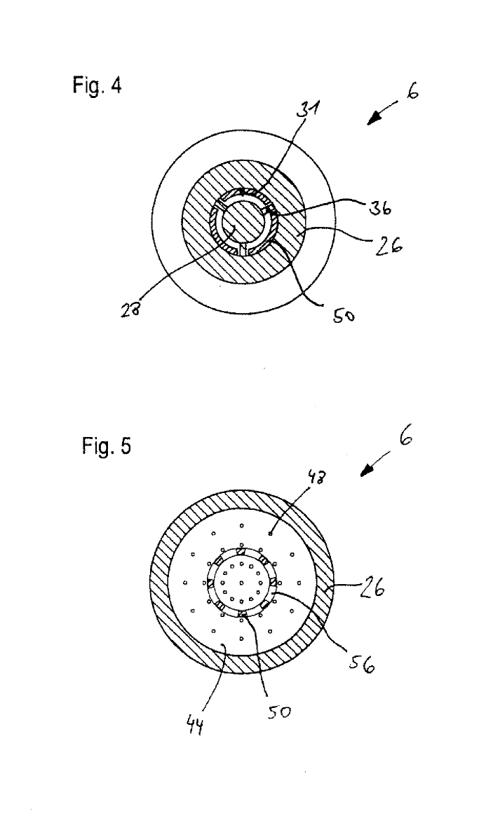

A first embodiment of the nozzle arrangement 6 will be described hereinbelow with reference to FIGS. 2-5. FIGS. 2 and 3 each show a schematic cross sectional view of a schematic nozzle arrangement 6 in different operational positions, while FIGS. 4 and 5 show cross sectional views along the lines IV-IV and V-V in FIG. 2, respectively.

The nozzle arrangements 6 are each substantially made up from a housing unit 22 and a setting unit 24. The housing unit has a housing body 26 and a flow guide element 28. The housing body 26 has an inlet opening 30, an outlet opening 31 and a flow space 32 arranged there-between. As may be recognized in FIG. 2, the flow space 32 has a flow cross section, which is substantially larger than the flow cross section of the inlet opening 30 and the flow cross section of the outlet opening 31. The flow space 32 has a tapered section, tapering towards the inlet opening 30 and a tapered section tapering towards the outlet opening 31, as well as an intermediate section having a constant cross section.

At the lower end of the housing body 26, a threaded extension 34 is provided, having an outer thread, for a threaded connection to a through opening 16 in the bottom wall of a CVD-reactor. A corresponding bottom wall 3 is schematically shown in FIG. 2 by a dashed line. The housing body 26 has a stepped configuration, corresponding to the stepped configuration of through opening 16 in bottom wall 3 of the CVD-reactor. The nozzle arrangement 6 may also be mounted in substance onto the bottom wall 3 and only the threaded extension 34 may extend into a through opening of the bottom wall. In the stepped section, the housing body 26 may be mounted in a sealing manner in the bottom wall 3. Preferably a thermally conducting element, such as a graphite or silver foil may be provided between the housing body 26 and the bottom wall 3, in order to facilitate cooling of the nozzle arrangement 6 via the bottom wall 3.

The flow guide element 28 is mounted in a centered manner within the outlet opening 31 of the housing body 26 via a plurality of bar or bridge elements 36, as is best shown in the sectional representation of FIG. 4. In the sectional representation, three bars 36 are provided, which connect the flow guide element 28 to the housing body 26 in a fixed manner and in a predetermined orientation.

The guide flow element 28 has a conical shape tapering upwards, as is best seen in the sectional representation of FIGS. 2 and 3.

The setting unit 24 consists in substance of a control part 40 and a setting part 42. The control part 40 is formed as a plate element 44. The plate element 44 has a circumferential shape corresponding to the interior circumferential shape of the flow space 32 (within the section of the constant cross section), and is movable therein upwards and downwards. A sealing element may be provided between the outer circumference of the plate element 44 and the inner circumference of the flow space 32, such as an O-ring. A lower position of the plate element 44 is limited by respective stops 46. This lower position is an idle position, as will be explained herein below.

The plate element 44 has a plurality of through openings 48. Therefore, the plate element 44 may be called a perforated plate, i.e. a plate having a plurality of holes. The sum of the flow cross sections of the through openings 48 is smaller than the flow cross section of the inlet opening 30 in the housing body 26. The perforated plate configuration can be best seen in the view according to FIG. 5.

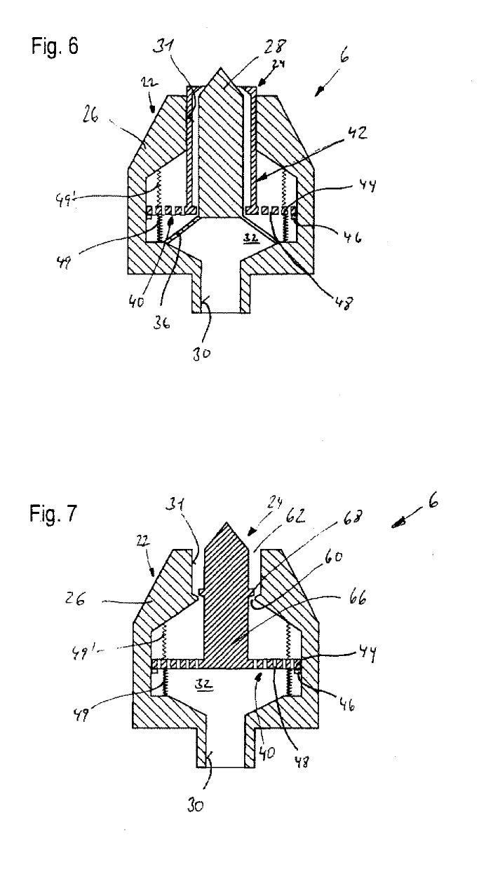

A biasing element in the shape of a spring 49 is provided between the lower side of flow guide element 28 and an upper side of the plate element 44. The biasing element biases the plate element 44 against the stop members 46, as seen in FIG. 2. In place of a spring 49, a different biasing element, such as an elastic body, a pneumatic or hydraulic piston and others may be provided. Furthermore, the biasing element may be arranged at a different position, in order to provide a respective biasing of the plate element 44 against the stop members 46. Such alternative arrangements are for example shown in FIGS. 6 and 7, which will be described herein below.

The setting part 42 is in substance a tube shaped, vertically extending tubular body 50, which is fixedly connected to the plate element 44 at its lower end or is integrally formed therewith. At its upper, free end the tubular body 50 has a taper 52 and an outlet opening 54. The tubular body has an outer circumference, corresponding to the inner circumference of the outlet opening 31 of the nozzle body 26 and is received and guided therein in a gliding manner. To this end, the outlet opening 31 and/or the outer circumference of the tubular element 50 may have a surface made of PTFE or a surface made of a different material having a low coefficient of friction. Though not shown in the drawings, a seal arrangement may be provided between the inner circumference of the outlet opening 31 and the outer circumference of the tubular body 50, which may for example consist of one or more O-rings.

The tubular body 50 is arranged such that it extends between flow guide element 28 and outlet opening 31 of the nozzle body 26. In a section of the tubular body 50, surrounding the flow guide element 28, three opening for allowing the bars 36 to extend therethrough are provided, as is shown in the sectional view of FIG. 4. At a lower section of the tubular body 50, which is adjacent to a plate element 44, a plurality of passages 56 is provided, to allow passage of a gas flow from a space radially outside the tubular body into an interior space thereof and towards the outlet opening 55, as can be seen by the skilled person.

The skilled person will realize, the outlet opening 54 in tubular body 50 forms the actual outlet opening of the nozzle arrangement. The outlet opening 54 may at least partially be blocked by the flow guide element 28. When the setting unit 24 is in the position shown in FIG. 2, the conical portion of the flow guide element 28 extends into the outlet opening 54 and thus reduces the effective flow area of the outlet opening 54. Upon an upwards movement of the setting unit 24, the flow cross section of the outlet opening 54 is successively deblocked, until a maximum flow cross section is formed, as shown in FIG. 3. In this position the flow guide element 28 completely deblocks the outlet opening 54. A movement of the setting unit 24 thus causes a change in the flow cross section of the outlet opening 54.

Operation of the nozzle arrangement 6 will be described herein below.

A process gas having a first flow rate and a first pressure is supplied into the flow space 32 via the inlet opening 30 in the nozzle body 26. The gas flows through the through openings 48 in a plate element 44 and causes a loss of pressure in so doing. This loss of pressure depends on the flow rate and the pressure of the process gas supplied via the inlet opening 30. If the pressure and the flow rate is below a predetermined threshold, the plate element 44 remains in the position shown in FIG. 2, since the loss of pressure is not sufficient to move the plate element 44 upwards against the biasing force exerted by spring 49. If the pressure and flow rate, however, are increased above a first threshold, the loss of pressure across the plate element 44 is high enough such that the plate element 44 is moved upwards against the biasing force provided by the spring. The plate element 44 may be moved upwards enough to completely deblock the outlet opening 54 of tubular body 50, as shown in FIG. 3. This movement may also be limited by a stop member similar to stop member 46. This may be achieved by a predetermined pressure and a predetermined flow rate of the process gas through the inlet opening 30. The skilled person will realize that the flow rate and the pressure of the process gas which is supplied may be adjusted such that the plate element 44 is in the lower most position according to FIG. 2, the uppermost position according to FIG. 3 or any other position therebetween. The nozzle arrangement 6 may be adjusted or designed such that a substantially constant flow velocity of the process gas exiting the outward opening 54 may be provided during a process at known pressures and flow rates. The term “substantially” is supposed to comprise a variation of up to +/−20%, and preferably <10%.

FIG. 6 shows an alternative embodiment of a nozzle arrangement 6 in cross section, similar to the representation of FIG. 2. In the following description the same reference signs are used for the same or similar elements.

The nozzle arrangement 6 again has a housing unit 22 and a setting unit 24. The housing unit has a housing body 26 and a flow guide element 28. The housing body 26 has an inlet, an outlet and a flow space 32 therebetween, which are arranged and designed in the same manner as previously described. However, no bars 36 are provided in the outlet opening 31 in order to mount the flow guide element 28. In the embodiment according to FIG. 6, the flow guide element 28 is elongated and is connected to the bottom of the flow space 32 via respective bars or bridges 36. Between the bars 36 free spaces are provided, in order to provide a substantially free flow of gas within the flow space 32.

The setting unit 24 again has in substance a control part 40 and a setting part 42. The control part 40 is again a plate element 44, which in this embodiment, however, has a large central opening for allowing the flow guide element 28 to be guided therethrough. In the remaining part of the plate element 44 a plurality of through openings 48 is provided. The plate element 44 again is arranged within the flow space such that it may move upwards and downwards, wherein the lower position of the plate element 44 is limited by stop members 46.

The plate element 44 is biased towards the stop members 46 by a biasing element. The biasing element may for example be a tension spring 49, which extends between a lower side of the plate element 44 and a bottom of the flow space 32, or a pressure spring, extending between an upper side of the plate element 44 towards a top portion of the flow space 32, as indicated by the dashed line 49. In place of the spring also an elastomeric ring or a similar element may be used.

The setting part 42 is designed in substance in the same manner as previously described, wherein, however, through openings for bars 36 do not have to be provided in tubular body 50.

Operation of the nozzle arrangement 6 is in substance the same as previously described, and therefore reference is made to the previous description in order to avoid undue repetitions.

FIG. 7 shows a third embodiment of a nozzle arrangement 6. Again, the same reference signs are used as in the previous embodiments, for the same or similar elements.

The nozzle arrangement 6 again has a housing unit 22 as well as a setting unit 24. In this embodiment the housing unit 22 has a housing body 26 but no flow guide element. The housing body 26 has an inlet 30, an outlet 31 and a flow space 32 therebetween. The inlet 30 and the flow space 32 are designed in the same manner as in the embodiment according to FIG. 2. The outlet opening 31 has a stepped contour which in a lower inlet section 60 thereof has a smaller flow cross section than in an upper outlet section 62 thereof.

The setting unit 24 again consists in substance of a control part 40 and a setting part 42. The control part 40 is again formed as a plate element 44 having a plurality of through openings 48. The plate element 44 may again be biased against stop members 46 in flow space 32 via a biasing element, such as a tension spring 49 or a pressure spring as indicated at 49′.

The setting portion 42 is formed as a pillar shaped element 66, which extends in a vertical direction and which is fixedly connected to plate element 44 at its lower end. The pillar shaped element 66 has a taper at its upper, free end. The pillar shaped element 66 has a circumferential shape corresponding to the shape of outlet opening 31. The pillar shaped element 66 furthermore has a radially extending projection 68, which is arranged within the area of the outlet opening 31, above the stepped section of the outlet opening 31. As shown in FIG. 7, the projection 68 reduces the flow cross section formed between projection 68 and the step in the outlet opening 31 of housing body 26 when the plate element 44 is biased against stop members 46. Upon movement of the plate element 44 away from the stop members, the flow cross section is enlarged.

The nozzle arrangement 6 thus also provides the possibility to dynamically vary the outlet flow cross section during its operation.

Thus, the effects are in substance the same as previously described such that no further description with respect to operation of the apparatus appears to be necessary.

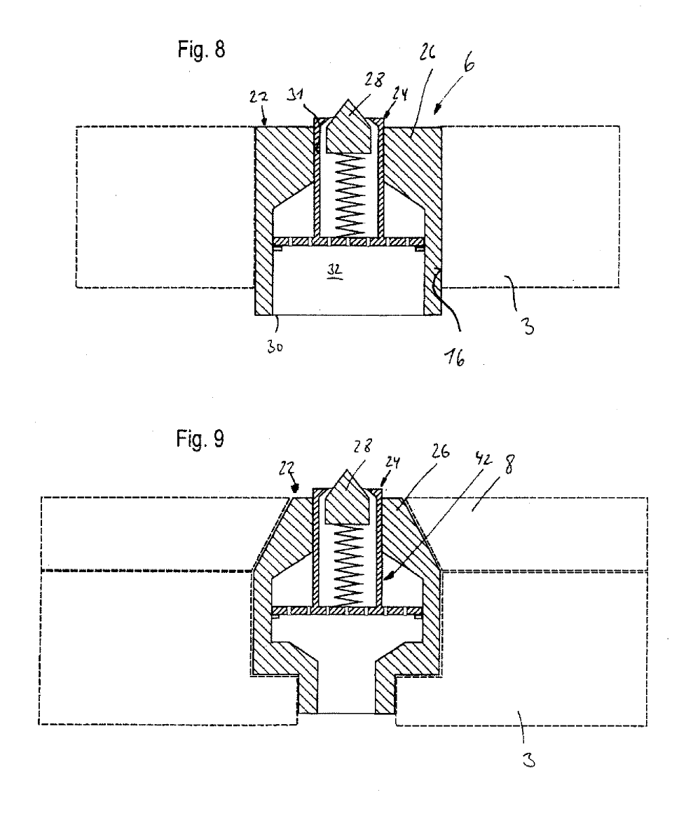

FIG. 8 shows a fourth embodiment of a nozzle arrangement 6, as it is mounted in a bottom 3 of a CVD reactor.

In this embodiment, the nozzle arrangement again has a housing unit 22 and a setting unit 24. The housing unit 22 has a housing body 26, which in this embodiment, has a straight cylindrical circumferential shape corresponding to the interior circumferential shape of a through opening 16 in bottom 3 of the CVD reactor. The housing body 26 may be mounted in any suitable manner within the through opening 16, such as for example a threaded connection. Even though this is not shown, the housing body 26 may have a radially outwardly extending flange at its lower end, which may for example be mounted in a ceiling manner against the lower surface of bottom wall 3. A respective flange may also be provided at the upper end of housing body 26.

An upper surface of housing body 26 is plane and is in substance flush to an upper surface of bottom wall 3 of the CVD reactor, when it is mounted in the through opening 16. Alternatively, the upper side of housing body 26 may also be flush with the upper side of insulating unit 8, which is shown in FIG. 1. The housing body 26 does not or at least not substantially extend into a free portion of the process space of CVD reactor 1.

The housing body 26 has an inlet opening 30, an outlet opening 31 and a flow space 32 arranged therebetween. In this embodiment, the inlet opening 30 has the same flow cross section as the flow space 32, while the outlet opening 31 again has a smaller flow cross section. Alternatively it would also be possible to again have an inlet opening 30, having a smaller diameter such as in the embodiment of FIG. 2. In this embodiment it is important that the housing body 26 is in substance completely received in the bottom wall (the insulation 8) and does not or at least not in a substantial way extend into a free portion of the process chamber. In this embodiment, mounting of the nozzle arrangement 6 from below into the through opening 16 of the bottom wall 3 is possible, even though mounting may typically also occur from above.

In other aspects, this embodiment corresponds with respect to the design of the flow guide element 28 and the setting unit to the embodiment according to FIG. 2 such that a detailed description thereof is omitted, in order to avoid undue repetitions.

FIG. 9 shows a specific option for arranging a nozzle arrangement 6, which may have the same design as the nozzle arrangement 6 according to FIG. 2. The housing body 26 of nozzle arrangement 6 has a taper at its upper end, and a step at its lower end, as previously described. A main portion of the lower end is received within a stepped through opening 16 of the bottom wall 3, while the upper, tapering section is partially covered by the insulation 8. An upper side of housing body 26 is flush to an upper side of insulation 8. Again the housing body 16 does not extend into a free portion of the process chamber of the CVD reactor. Only the flow guide element 28 and the setting part 42 of the setting unit 24 extend into the process space. This may again lead to an advantageous distribution of a gas flow supplied to the process space via the nozzle arrangement 6.

The invention was described above with respect to preferred embodiments thereof, without being limited to these embodiments. In particular, features of the different embodiments may be freely combined or replaced by each other.

The skilled person will realize many alternative embodiments, which fall within the spirit and scope of the following claims.

1. Nozzle arrangement for use in a CVD reactor, comprising;
a nozzle body having an inlet, an outlet and a flow space arranged therebetween;
at least one control unit having a control part and a setting part, wherein the control part is arranged in a movable manner within the flow space and the control part defines a flow cross section within the flow space, which is sufficiently small to cause a loss of pressure at the control part upon a flow of gas through the nozzle body, which loss of pressure biases the control part within the flow space toward the outlet, wherein the setting part is movable together with the control part and comprises a section, which upon movement of the setting part varies the flow cross section of the outlet; and
at least one biasing element, which biases the control part within the flow space in a direction away from the outlet.

2. Nozzle arrangement according to claim 1, wherein the control part is formed as a perforated plate or comprises a perforated plate section;

3. Nozzle arrangement according to claim 1, wherein the setting part is formed such that the flow cross section at the outlet is increased upon a movement of the control part towards the outlet and is reduced upon a movement in the opposite direction;

4. Nozzle arrangement according to claim 1, wherein the setting part is formed such that upon a movement thereof, the flow angle of the outlet is varied.

5. Nozzle arrangement according to claim 4, wherein the setting part is designed to reduce the flow angle upon a movement of the control part towards the outlet and to enlarge the same upon a movement in the opposite direction.

6. Nozzle arrangement according to claim 1, wherein the movement of the control part and/or the setting part is guided in a gliding manner by the nozzle body.

7. Nozzle arrangement according to claim 6, wherein that at least one of the elements forming the guide has a surface made from PTFE.

8. Nozzle arrangement according to claim 1, wherein the nozzle body has an outlet opening section and at least one flow guide element stationary mounted at least partially within the outlet opening section, wherein the setting part comprises a tubular section which is arranged at least partially in said outlet opening section and surrounds the at least one flow guide element.

9. Nozzle arrangement according to claim 1, wherein the flow cross section defined by the control part is smaller than the flow cross section of the inlet.

10. CVD-reactor having a process chamber defining a process space, said process chamber having a bottom wall comprising:
at least one through opening, in which a nozzle arrangement according to any one of the preceding claims is at least partially received.

11. CVD-reactor according to claim 9, wherein the nozzle arrangement is in substance completely arranged in the through opening.

12. CVD-reactor according to claim 9, wherein the through opening is stepped such that it has a first section directed adjacent to the process space which has a larger diameter than a directly adjacent second section thereof, wherein a main portion of the nozzle arrangement is received in the first section of the through opening.

13. CVD-reactor according to claim 11, wherein an axially facing shoulder is formed between the first and second sections of the through opening, and the nozzle arrangement is arranged in sealing manner against said shoulder.

14. CVD-reactor according to claim 9, wherein the process chamber comprises a cooling arrangement for cooling the bottom wall thereof and the nozzle arrangement is mounted in a thermally conducting relationship to the bottom wall.
